(19) United States
(12) Patent Application Publication
(10) Pub. No.: US 2024/0404982 A1
(43) Pub. Date: Dec. 5, 2024

(54) POWER SEMICONDUCTOR MODULE HAVING A METALLIC CLIP WITH ULTRASONICALLY WELDED CONTACT REGIONS AND METHOD OF PRODUCING THE POWER SEMICONDUCTOR MODULE

(71) Applicant: Infineon Technologies AG, Neubiberg (DE)

(72) Inventors: Marian Sebastian Broll, Soest (DE); Daniel Obermeier, Ensdorf (DE); Florian Alexander Biermann, Gladbeck (DE)

(21) Appl. No.: 18/205,180

(22) Filed: Jun. 2, 2023

(51) Int. Cl. H01L 23/00; H01L 21/607; H01L 23/495; H01L 25/065

(52) U.S. Cl. CPC H01L 24/72; H01L 21/607; H01L 23/49524; H01L 23/49575; H01L 24/08; H01L 24/73; H01L 25/0655; H01L 25/0657; H01L 2224/08175; H01L 2224/72; H01L 2224/73265; H01L 2924/01029

(57) ABSTRACT

A power semiconductor module includes: a first substrate; a first power semiconductor die attached to the first substrate; and a first metallic clip having a plurality of first contact regions ultrasonically welded to either a first metallic region of the first substrate or a first metallic region of the first power semiconductor die. The first contact regions of the first metallic clip are laterally separated from one another by a first gap in the first metallic clip. Additional power semiconductor module embodiments and corresponding methods of production are also described herein.

### BACKGROUND

For power semiconductor modules with more than one substrate, wire bonds or ribbons are often used to electrically connect semiconductor dies (chips) attached to the substrates. Using a copper clip instead of wires or ribbons for the semiconductor front-side connections enables lower electrical inductance and higher current carrying capability. State-of-the-art technology for the application of a copper clip as the front-side die interconnect in power semiconductor modules is soldering or sintering. Ultrasonic welding is not typically used for several reasons. For example, mechanical loading conditions during ultrasonic welding of a copper clip to the front side of a semiconductor die results in chip cracks for common chip technologies. Also, improper clip design and clamping prevent the transmission of sufficient ultrasonic power from the welding sonotrode to the welding interface due to the spring resistance of copper clips. In addition, clip lift-off occurs due to the interaction between several welding spots by ultrasonic vibration transmission. More than one welding spot per die is often required to enable sufficient contact area. However, the transmission of ultrasonic vibration may damage already welded spots of a partly fixed clip. Furthermore, ultrasonic amplitude and frequency (e.g., several kHz) may cause clip fatigue (cracks), especially for clip designs with high mechanical stress peaks such as at the clip edges.

Hence, there is a need for an improved power semiconductor module design that is compatible with ultrasonic welding technology.

### SUMMARY

According to an embodiment of a power semiconductor module, the power semiconductor module comprises: a first substrate; a first power semiconductor die attached to the first substrate; and a first metallic clip having a plurality of first contact regions ultrasonically welded to either a first metallic region of the first substrate or a first metallic region of the first power semiconductor die, wherein the first contact regions of the first metallic clip are laterally separated from one another by a first gap in the first metallic clip.

According to another embodiment of a power semiconductor module, the power semiconductor module comprises: a first substrate; a second substrate; a plurality of first power semiconductor dies attached to a first metallic region of the first substrate; a plurality of second power semiconductor dies attached to a first metallic region of the second substrate; a first metallic clip having a plurality of first contact regions ultrasonically welded to a first metallic region of each of the first power semiconductor dies; and a second metallic clip having a plurality of first contact regions ultrasonically welded to the first metallic region of the first substrate and a plurality of second contact regions ultrasonically welded to a first metallic region of each of the second power semiconductor dies, wherein each group of the first contact regions of the first metallic clip ultrasonically welded to the first metallic region of the same first power semiconductor die are laterally separated from one another by a first gap in the first metallic clip, wherein the first contact regions of the second metallic clip are laterally separated from one another by a first gap in the second metallic clip, wherein each group of the second contact regions of the second metallic clip ultrasonically welded to the first metallic region of the same second power semiconductor die are laterally separated from one another by a second gap in the second metallic clip.

According to an embodiment of a method of producing a power semiconductor module, the method comprises: attaching a first power semiconductor die to a first substrate; placing a first metallic clip over the first substrate, the first metallic clip having a plurality of first contact regions laterally separated from one another by a first gap in the first metallic clip; and ultrasonically welding the first contact regions of the first metallic clip to either a first metallic region of the first substrate or a first metallic region of the first power semiconductor die.

According to another embodiment of a power semiconductor module, the power semiconductor module comprises: a first substrate; a first power semiconductor die attached to the first substrate; and a first metallic clip having a plurality of first contact regions ultrasonically welded to either a first metallic region of the first substrate or a first metallic region of the first power semiconductor die, wherein the first contact regions are laterally separated from one another by a first gap in the first metallic clip, wherein the first contact regions of the first metallic clip are connected to a body region of the first metallic clip by a first level transition region of the first metallic clip such that the first contact regions are disposed at a first level and the body region is disposed at a second level different than the first level, wherein the first level is closer to the first substrate than the second level.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial top plan view of an embodiment of a substrate, a power semiconductor die, and a metallic clip included in a power semiconductor module.

FIG. 2 illustrates a partial cross-sectional view of the power semiconductor module, in the region of two (2) power semiconductor dies attached to the same metallic region of the top metallized side of the substrate.

FIG. 3 illustrates a partial top plan view of the power semiconductor module and applies the same approach illustrated in FIG. 2, but to the top metallized side of the substrate.

FIG. 4 illustrates the same partial cross-sectional view of the power semiconductor module as shown in FIG. 2, but with the metallic clip having a downset feature.

FIG. 5 illustrates the same partial top plan view of the power semiconductor module as shown in FIG. 3, but with the clip downset feature illustrated in FIG. 4.

FIG. 6 illustrates a partial top plan view (upper part of FIG. 6) and a corresponding cross-sectional view (lower part of FIG. 6) of the clip downset feature.

FIG. 7 illustrates a partial top perspective view of a clip frame that provides multiple metallic clips each having both the downset and gap features.

FIG. 8 illustrates a cross-sectional view of the assembly shown in FIG. 7, along the line labelled A-A′ in FIG. 7.

### DETAILED DESCRIPTION

The embodiments described herein provide a power semiconductor module design that is compatible with ultrasonic welding technology. The power semiconductor module design is robust against chip (die) cracking, clip lift-off and clip fatigue. The power semiconductor module design includes a power semiconductor die that is attached to a substrate and a metallic clip having first contact regions (feet) that are ultrasonically welded to either a metallic region of the substrate or a metallic region of the power semiconductor die. The first contact regions/feet of the metallic clip are laterally separated from one another by a gap in the metallic clip, which increases the distance over which ultrasonic vibrations must travel from one ultrasonic weld site to another ultrasonic weld site. The metallic clip and/or the semiconductor die may have one or more additional features, described later herein, to further increase the robustness of the power semiconductor module against chip cracking, clip lift-off and clip fatigue. More than one power semiconductor die may be attached to the substrate and more than one substrate may be included in the power semiconductor module.

Described next, with reference to the figures, are exemplary embodiments of the power semiconductor module and methods of producing the power semiconductor module. Any of the embodiments described next may be used interchangeably unless otherwise expressly stated.

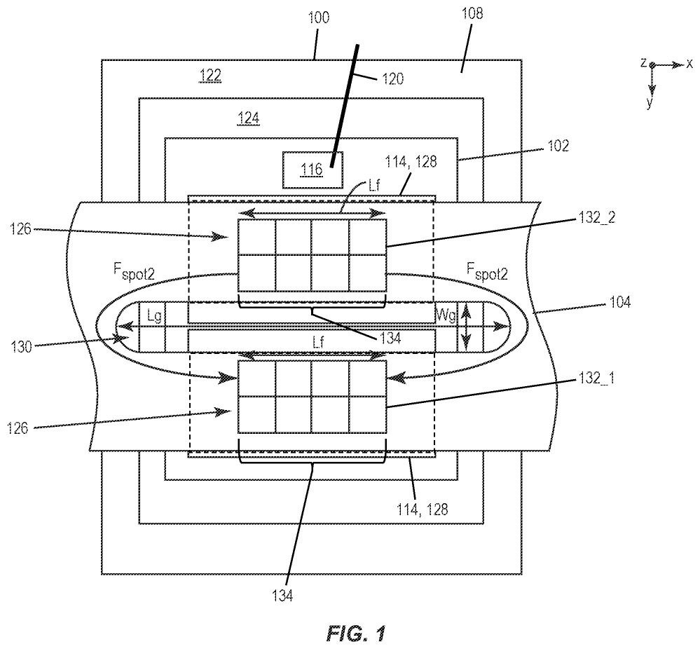

FIG. 1 illustrates a partial top plan view of an embodiment of a substrate 100, a power semiconductor die 102, and a metallic clip 104 included in the power semiconductor module. The power semiconductor module may form part of a power electronics circuit for use in various power applications such as in a DC/AC inverter, a DC/DC converter, an AC/DC converter, a DC/AC converter, an AC/AC converter, a multi-phase inverter, an H-bridge, etc. More than one power semiconductor die 102 may be attached to the substrate 100 and more than one substrate 100 may be included in the power semiconductor module.

Each substrate 100 may be, e.g., a DBC (direct bonded copper) substrate, an AMB (active metal brazed) substrate, or an IMS (insulated metal substrates), where in each case an insulating body 106 such as a ceramic separates top and bottom metallized sides 108, 110 of the substrate 100 from one another, where the insulating body 106 and the bottom metallized side 110 of the substrate 100 are both out of view in FIG. 1. Each substrate 100 instead may be a lead frame, for example.

Each power semiconductor die 102 may comprise one or more semiconductor materials that are used to form a power semiconductor device such as, e.g., a power Si or SiC power MOSFET (metal-oxide-semiconductor field-effect transistor), a HEMT (high-electron mobility transistor), an IGBT (insulated-gate bipolar transistor), a JFET (junction filed-effect transistor), a power diode, etc. For example, each power semiconductor die 102 may comprise Si, silicon carbide (SIC), germanium (Ge), silicon germanium (SiGe), gallium nitride (GaN), gallium arsenide (GaAs), and the like.

In FIG. 1, the power semiconductor die 102 is a vertical power transistor die. For a vertical power transistor die 102, the primary current flow path is between the front and back sides of the die 102. The drain terminal 112 is typically disposed at the backside of the die 102, with the source terminal 114 and the gate terminal 116 at the die frontside, where the drain terminal 112 is out of view in FIG. 1. Although not apparent in FIG. 1 due to the partial view, the top metallized side 108 of the substrate 100 may be patterned and the gate terminal 116 of the power transistor die 102 may be electrically connected to a corresponding metallic region 118 of the patterned top side metallization 108 by a bond wire 120.

In the case of two or more power transistor dies 102 included in the power semiconductor module, the power transistor dies 102 may be electrically interconnected to form a power electronics circuit such as a half bridge, e.g., with one or more first power transistor dies 102_1 forming a high-side switch of the half bridge and one or more second power transistor dies 102_2 forming a low-side switch of the half bridge. In the case of a half bridge formed by one or more first and one or more second power transistor dies 102_1, 102_2, the metallic clip 104 may provide a switch node connection to the half bridge. Additional types of semiconductor dies may be included in the power semiconductor module, such as power diode dies, logic dies, controller dies, gate driver dies, etc.

In FIG. 1, the power semiconductor die 102 is attached to a corresponding metallic region 122 of the top metallized side 108 of the substrate 100 by a joint 124 such as a weld joint, a braze joint, a solder joint, an adhesive joint, etc. In FIG. 1, the metallic clip 104 has a plurality of first contact regions (feet) 126 ultrasonically welded to a metallic region 128 of the power semiconductor die 102. The first contact regions/feet 126 of the metallic clip 104 may comprise Cu (copper), have a thickness in a range of 150 to 500 μm, a Cu purity >97%, and a mechanical strength (breaking load) in a range of 180 to 500 MPa, as an example. However, other types of clips may be used as the metallic clip 104.

Ultrasonic welding involves local application of high-frequency (e.g., several kHz) ultrasonic acoustic vibrations to work pieces that may be held together under pressure to create a solid-state weld. The first contact regions/feet 126 of the metallic clip 104 are laterally separated from one another in the y direction in FIG. 1 by a gap 130 in the metallic clip 104, to reduce interactions between the ultrasonic welding spots 132 that attach the first contact regions/feet 126 to the metallic region 128 of the power semiconductor die 102 and therefore reduce the likelihood of clip fatigue (cracks). That is, the ultrasonic welding spots 132 are decoupled from one another by the gap 130. In FIG. 1, a second welding spot 132_2 is ultrasonically welded after a first ultrasonic welding spot 132_1. Accordingly, the metallic clip 104 is partly fixed to the metallic region 128 of the power semiconductor die 102 while the second ultrasonic welding spot 132_2 is being formed.

Due to the gap 103, the vibrational force ‘Fspot2’ that arises because of the amplitude and frequency (e.g., several kHz) applied during ultrasonic welding of the second welding spot 132_2 has a longer distance to travel before reaching the previously formed first ultrasonic welding spot 132_1, which dampens the vibrational force Fspot2 and reduces the likelihood of clip lift-off and clip fatigue. In one embodiment, the length ‘Lg’ of the gap 130 between two adjacent welding spots 132 is greater than the length ‘Lf’ of the welding spots 132. The length Lf of the welding spots 132 is approximately equal to the size of the tip of the ultrasonic welder sonotrode (not shown in FIG. 1) that applies vibrational energy to the first contact regions/feet 126 of the metallic clip 104. The width ‘Wg’ of the gap 130 may be limited by the size of the power semiconductor die 102 and the number of first contact regions/feet 126. The gap 130 that laterally separates the first contact regions/feet 126 of the metallic clip 104 from one another may have rounded corners as shown in FIG. 1, to avoid sharp edges which further enhances robustness against clip lift-off and clip fatigue.

The surface of each first contact region/foot 126 of the metallic clip 104 that faces away from the substrate 100 has a sonotrode imprint 134, from the tip of the ultrasonic welder sonotrode that contacts the first contact region/foot 126 during ultrasonic welding. The sonotrode imprint 134 may have a honeycomb pattern, for example. The sonotrode imprint 134 may have other shapes such as a square shape (e.g., 1×1 mm, 4×4 mm, etc.), a rectangular shape (e.g., 2×3 mm, 8×12 mm, etc.), etc. In one embodiment, each first contact region/foot 126 of the metallic clip 104 has an area that is less than 4 times the area of the sonotrode imprint 134. In FIG. 1, the area of each first contact region/foot 126 of the metallic clip 104 is indicated by a dashed rectangle.

In one embodiment, the metallic region 128 of the power semiconductor die 102 to which the first contact regions/feet 126 of the metallic clip 104 are ultrasonically welded is a bond pad (e.g., a source bond pad) that has a thickness in the z direction in FIG. 1 greater than 5 μm (microns) to enhance robustness against chip (die) cracking. For example, the bond pad may comprise Cu (copper) having a thickness of at least 5 μm (e.g., 10 μm or thicker) and further include a Cu diffusion barrier layer such as W, Ti, WTi, TiN, and/or TaN, etc.

In one embodiment, the metallic region 128 of the power semiconductor die 102 to which the first contact regions/feet 126 of the metallic clip 104 are ultrasonically welded is a metallic plate attached to a bond pad of the power semiconductor die 102. The metallic plate may be connected by soldering, sintering, etc. to the die bond pad to enable ultrasonic welding of the metallic clip 104.

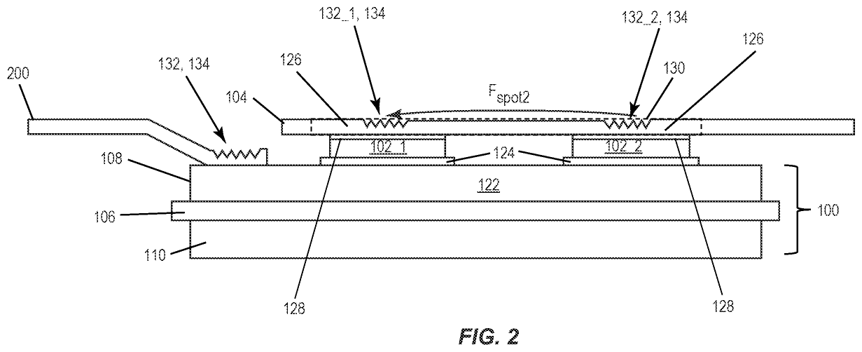

FIG. 2 illustrates a partial cross-sectional view of the power semiconductor module, in the region of two (2) power semiconductor dies 102_1, 102_2 attached to the same metallic region 122 of the top metallized side 108 of the substrate 100. A metallic region 128 such as a die pad or metallic plate at the top side of each power semiconductor die 102 are electrically connected to each other through the first contact regions/feet 126 of the metallic clip 104. The gap 130 that laterally separates the first contact regions/feet 126 of the metallic clip 104 from one another is out of the illustrated plane in FIG. 1, but increases the distance of the path over which the vibrational force ‘Fspot2’ that arises during ultrasonic welding of a second welding spot 132_2 to the second semiconductor die 102_2 has to travel before reaching a previously formed first ultrasonic welding spot 132_1 to the first semiconductor die 102_1, dampening the vibrational force Fspot2 and thereby reducing the likelihood of clip lift-off and clip fatigue. An additional metallic clip 200 may be ultrasonically welded to the top metallized side 108 of the substrate 100.

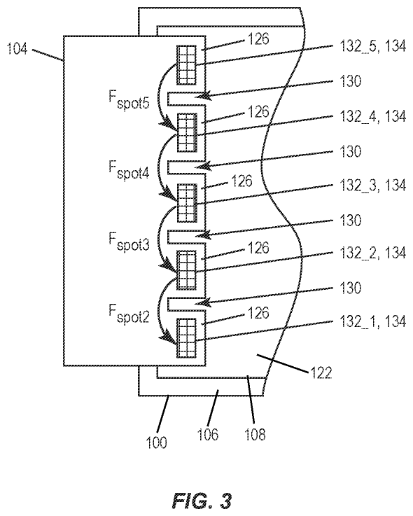

FIG. 3 illustrates a partial top plan view of the power semiconductor module and utilizes the same clip gap feature illustrated in FIG. 2, but for the top metallized side 108 of the substrate 100. In FIG. 3, the metallic clip 104 has five (5) first contact regions/feet 126 that are ultrasonically welded to the top metallized side 108 of the substrate 100. A gap 130 is formed in the metallic clip 104 that laterally separates adjacent ones of the first contact regions/feet 126 of the metallic clip 104 from one another. Accordingly, the distance of the path over which the vibrational force ‘FspotX’ that arises during ultrasonic welding of a subsequent welding spot 132_X to the top metallized side 108 of the substrate 100 must travel before reaching the previously formed ultrasonic welding spot 132_X−1 increases, thereby dampening the vibrational force FspotX.

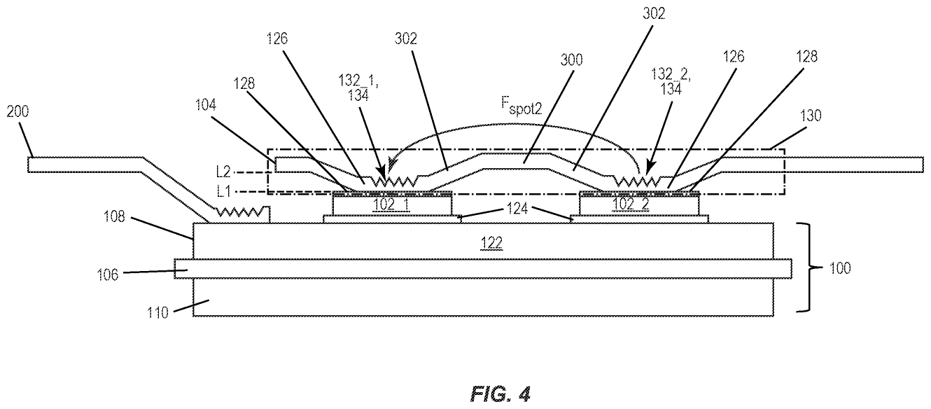

FIG. 4 illustrates the same partial cross-sectional view of the power semiconductor module as shown in FIG. 2, but with the metallic clip 104 having a downset feature that includes a body region 300 and a level transition region 302. The first contact regions/feet 126 of the metallic clip 104 are connected to the body region 300 of the metallic clip 104 by the level transition region 302 of the metallic clip 104, such that the first contact regions/feet 126 are disposed at a first level L1 and the body region 300 is disposed at a second level L2 different than the first level L1. The first level L1 is closer to the substrate 100 than the second level L2, and the level transition region 302 provides a height transition between the first and second levels L1, L2. In one embodiment, the down-set height (L2-L1) is greater than 200 μm.

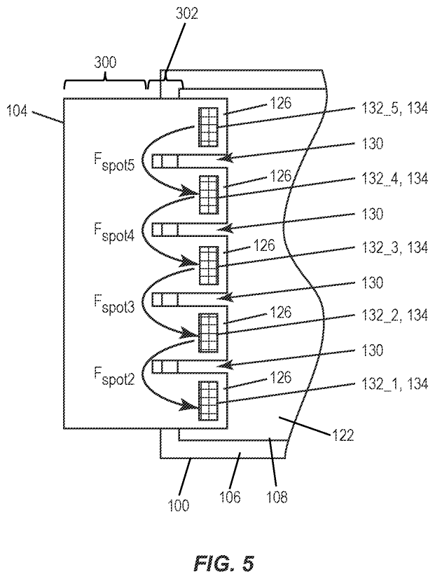

FIG. 5 illustrates the same partial top plan view of the power semiconductor module as shown in FIG. 3, but with the clip downset feature illustrated in FIG. 4.

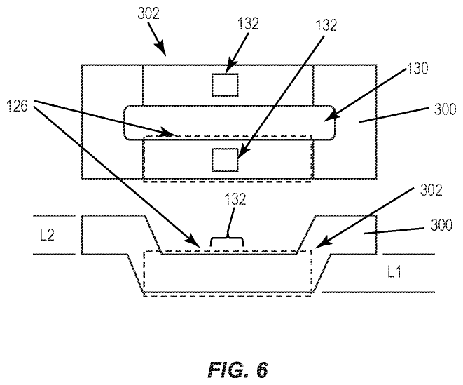

FIG. 6 illustrates a partial top plan view (upper part of FIG. 6) and a corresponding cross-sectional view (lower part of FIG. 6) of the clip downset feature. According to this embodiment, the gap 130 in the downset region is enclosed on all four (4) sides, e.g., in the case of the metallic clip 104 being used to contact multiple dies.

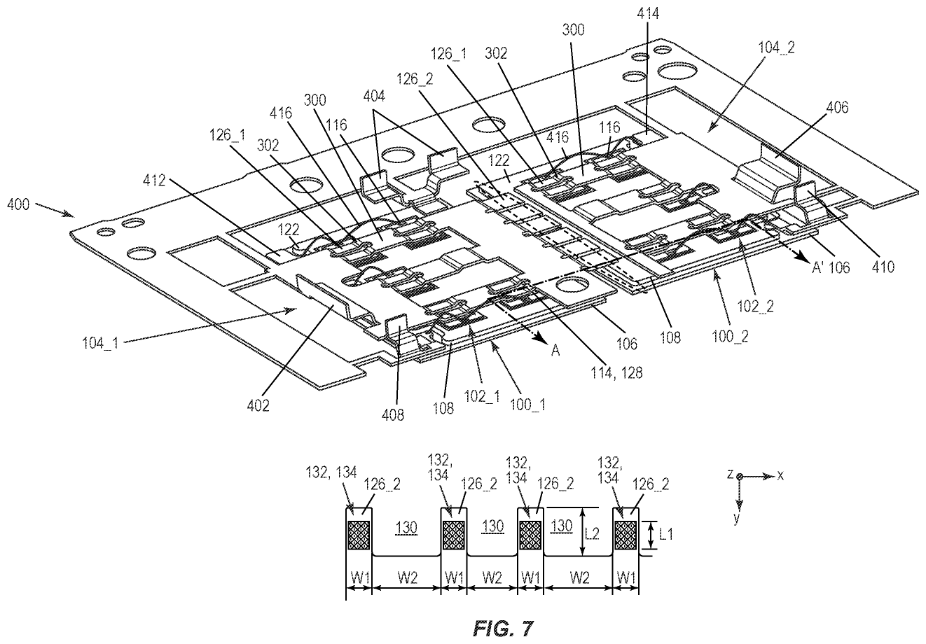

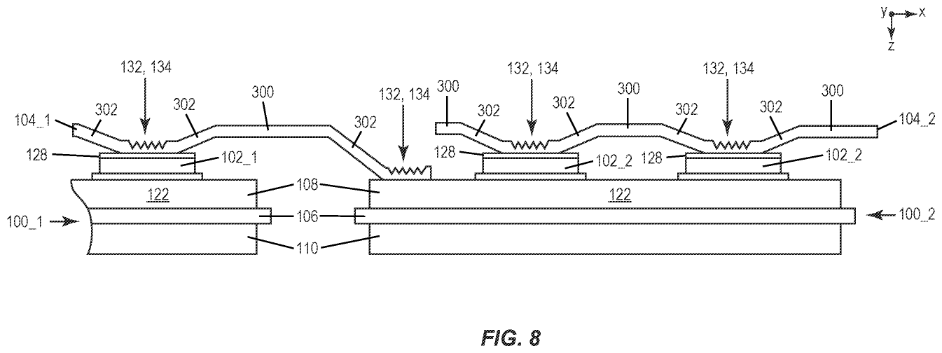

FIG. 7 illustrates a partial top perspective view of a clip frame 400 that provides multiple metallic clips 104 each having both the downset and gap features described herein. Combining the gap and downset features further decouples the ultrasonic welding forces, where the maximum decoupling effect is achieved by overlapping the gap 130 with the downset. FIG. 8 illustrates a cross-sectional view of the assembly shown in FIG. 7, along the line labelled A-A′ in FIG. 7.

In FIGS. 7 and 8, the clip frame 400 is aligned with first and second substrates 100_1, 100_2 during the module production process. A plurality of first power semiconductor dies 102_1 are attached to the first substrate 100_1 and a plurality of second power semiconductor dies 102_2 are attached to the second substrate 100_2. For example, the power semiconductor dies 102_1 attached to the first substrate 100_1 may be electrically coupled in parallel to form a high-side switch device of a half bridge and the power semiconductor dies 102_2 attached to the second substrate 100_2 may be electrically coupled in parallel to form a low-side switch device of the half bridge.

The first metallic clip 104_1 may include an AC bus bar 402 that is connected to the switch node of the half bridge, e.g., by having a group of first contact regions/feet 126_1 ultrasonically welded to the source terminal 114 of each first power semiconductor die 102_1 that forms the high-side switch device and a group of second contact regions/feet 126_2 ultrasonically welded to the metallic region 122 of the top metallized side 108 of the second substrate 100_2 which is at the drain potential of the low-side switch device. The first metallic clip 104_1 may further include one or more positive (+) DC bus bars 404 ultrasonically welded to the metallic region 122 of the top metallized side 108 of the first substrate 100_1, to provide drain potential to the first power semiconductor dies 102_1 which form the high-side switch device.

The second metallic clip 104_2 may include one or more negative (−) DC bus bars 406 having a group of first contact regions/feet 126_1 ultrasonically welded to the source terminal 114 of each second power semiconductor die 102_2 that forms the low-side switch device. Both metallic clips 104_1, 104_2 may also include gate leads 408, 410 for providing gate connections to the first and second power semiconductor dies 102_1, 102_2, respectively, and other terminals (not shown) such as sense terminals, for example. The gate leads 408, 410 of the respective metallic clips 104_1, 104_2 may be ultrasonically welded to a corresponding metallic region 412, 414 of the top metallized side 108 of the respective substrates 100_1, 100_2. The gate terminal 116 of each power semiconductor die 102_1, 102_2 is electrically connected to the gate metallic region 412, 414 of the top metallized side 108 of the respective substrates 100_1, 100_2, e.g., by bond wires 416.

The dashed oval shape in FIG. 7 emphasizes a region of the first metallic clip 104_1 where the group of second contact regions/feet 126_2 of the first metallic clip 104_1 is ultrasonically welded to the metallic region 122 of the top metallized side 108 of the second substrate 100_2, e.g., to form part of a half bridge switch node connection. The lower part of FIG. 7 illustrates a top plan view of several of the second contact regions/feet 126_2 of the first metallic clip 104_1 in the emphasized oval region.

In one embodiment, a linear dimension ‘W2’ of the gap 130 in the first metallic clip 104_1 measured in a lateral direction (x direction in the lower part of FIG. 7) between the second contact regions/feet 126_2 of the first metallic clip 104_1 is greater than a linear dimension ‘W1’ of the second contact regions/feet 126_2 of the first metallic clip 104_1 measured in the same lateral direction. Separately or in combination, the surface of each of the second contact regions/feet 126_2 of the first metallic clip 104_1 that faces away from the first substrate 100_1 has an ultrasonic welding spot 132 with a sonotrode imprint 134, the adjacent gap 130 in the first metallic clip 104_1 may extend along a side of the sonotrode imprint 134, and the gap 130 may be longer (L2>L1) than the side of the sonotrode imprint 134, e.g., as previously explained herein in connection with FIG. 1. Some or all of the first contact regions/feet 126_1 of the first metallic clip 104_1 and/or some or all of the first contact regions/feet 126_1 of the second metallic clip 104_2 may have the same W2: W1 relationship and/or the same L2: L1 relationship shown in the lower part of FIG. 7 for the second contact regions/feet 126_2 of the first metallic clip 104_1.

Although the present disclosure is not so limited, the following numbered examples demonstrate one or more aspects of the disclosure.
Example 1. A power semiconductor module, comprising: a first substrate; a first power semiconductor die attached to the first substrate; and a first metallic clip having a plurality of first contact regions ultrasonically welded to either a first metallic region of the first substrate or a first metallic region of the first power semiconductor die, wherein the first contact regions of the first metallic clip are laterally separated from one another by a first gap in the first metallic clip.
Example 2. The power semiconductor module of example 1, wherein the first contact regions of the first metallic clip are connected to a body region of the first metallic clip by a level transition region of the first metallic clip such that the first contact regions are disposed at a first level and the body region is disposed at a second level different than the first level, and wherein the first level is closer to the first substrate than the second level.
Example 3. The power semiconductor module of example 1 or 2, further comprising: a second power semiconductor die attached to the first substrate, wherein the first contact regions of the first metallic clip are ultrasonically welded to the first metallic region of the first power semiconductor die, wherein the first metallic clip has a plurality of second contact regions ultrasonically welded to a first metallic region of the second power semiconductor die, wherein the second contact regions are laterally separated from one another by a second gap in the first metallic clip.
Example 4. The power semiconductor module of example 3, wherein the first contact regions of the first metallic clip are connected to a body region of the first metallic clip by a first level transition region of the first metallic clip and the second contact regions of the first metallic clip are connected to the body region by a second level transition region of the first metallic clip such that the first contact regions and the second contact regions are disposed at a first level and the body region is disposed at a second level different than the first level, and wherein the first level is closer to the first substrate than the second level.
Example 5. The power semiconductor module of example 1 or 2, further comprising: a second power semiconductor die attached to the first substrate; and a second metallic clip having a plurality of first contact regions ultrasonically welded to the first metallic region of the first substrate, wherein the first contact regions of the first metallic clip are ultrasonically welded to the first metallic region of the first power semiconductor die, wherein the first metallic clip has a plurality of second contact regions ultrasonically welded to a first metallic region of the second power semiconductor die, wherein the second contact regions are laterally separated from one another by a second gap in the first metallic clip.
Example 6. The power semiconductor module of example 5, wherein the first contact regions of the first metallic clip are connected to a body region of the first metallic clip by a first level transition region of the first metallic clip and the second contact regions of the first metallic clip are connected to the body region by a second level transition region of the first metallic clip such that the first contact regions and the second contact regions are disposed at a first level and the body region is disposed at a second level different than the first level, and wherein the first level is closer to the first substrate than the second level.
Example 7. The power semiconductor module of any of examples 1 through 6, wherein the first contact regions of the first metallic clip are ultrasonically welded to the first metallic region of the first power semiconductor die, wherein first metallic region of the first power semiconductor die is a bond pad, and wherein the bond pad has a thickness greater than 5 μm.
Example 8. The power semiconductor module of any of examples 1 through 6, wherein the first contact regions of the first metallic clip are ultrasonically welded to the first metallic region of the first power semiconductor die, and wherein the first metallic region of the first power semiconductor die is a metallic plate attached to a bond pad of the first power semiconductor die.
Example 9. The power semiconductor module of any of examples 1 through 8, wherein a surface of each of the first contact regions of the first metallic clip that faces away from the first substrate has a sonotrode imprint, and wherein each of the first contact regions of the first metallic clip has an area that is less than 4 times an area of the sonotrode imprint.
Example 10. The power semiconductor module of any of examples 1 through 9, wherein a surface of each of the first contact regions of the first metallic clip that faces away from the first substrate has a sonotrode imprint, wherein the first gap in the first metallic clip extends along a side of the sonotrode imprint, and wherein the first gap in the first metallic clip is longer than the side of the sonotrode imprint.
Example 11. The power semiconductor module of any of examples 1 through 10, wherein a linear dimension of the first gap in the first metallic clip measured in a lateral direction between the first contact regions of the first metallic clip is greater than a linear dimension of the first contact regions of the first metallic clip measured in the same lateral direction.
Example 12. The power semiconductor module of any of examples 1 through 11, further comprising: a second substrate; a second power semiconductor die attached to the second substrate; and a second metallic clip having a plurality of first contact regions ultrasonically welded to the first metallic region of the first substrate and a plurality of second contact regions ultrasonically welded to a first metallic region of the second power semiconductor die, wherein the first contact regions of the first metallic clip are ultrasonically welded to the first metallic region of the first power semiconductor die, wherein the first contact regions of the second metallic clip are laterally separated from one another by a first gap in the second metallic clip, wherein the second contact regions of the second metallic clip are laterally separated from one another by a second gap in the second metallic clip.
Example 13. A power semiconductor module, comprising: a first substrate; a second substrate; a plurality of first power semiconductor dies attached to a first metallic region of the first substrate; a plurality of second power semiconductor dies attached to a first metallic region of the second substrate; a first metallic clip having a plurality of first contact regions ultrasonically welded to a first metallic region of each of the first power semiconductor dies; and a second metallic clip having a plurality of first contact regions ultrasonically welded to the first metallic region of the first substrate and a plurality of second contact regions ultrasonically welded to a first metallic region of each of the second power semiconductor dies, wherein each group of the first contact regions of the first metallic clip ultrasonically welded to the first metallic region of the same first power semiconductor die are laterally separated from one another by a first gap in the first metallic clip, wherein the first contact regions of the second metallic clip are laterally separated from one another by a first gap in the second metallic clip, wherein each group of the second contact regions of the second metallic clip ultrasonically welded to the first metallic region of the same second power semiconductor die are laterally separated from one another by a second gap in the second metallic clip.
Example 14. The power semiconductor module of example 13, wherein: each group of the first contact regions of the first metallic clip ultrasonically welded to the first metallic region of the same first power semiconductor die are connected to a body region of the first metallic clip by a level transition region of the first metallic clip such that the first contact regions of the first metallic clip are disposed at a first level and the body region of the first metallic clip is disposed at a second level different than the first level; each group of the second contact regions of the second metallic clip ultrasonically welded to the first metallic region of the same second power semiconductor die are connected to a body region of the second metallic clip by a level transition region of the second metallic clip such that the second contact regions of the second metallic clip are disposed at the first level and the body region of the second metallic clip is disposed at the second level; and the first level is closer to the first and second substrates than the second level.
Example 15. The power semiconductor module of example 13 or 14, wherein a surface of each of the first contact regions of the first metallic clip that faces away from the first substrate has a sonotrode imprint and an area that is less than 4 times an area of the sonotrode imprint, wherein a surface of each of the second contact regions of the second metallic clip that faces away from the second substrate has a sonotrode imprint and an area that is less than 4 times an area of the sonotrode imprint.
Example 16. The power semiconductor module of any of examples 13 through 15, wherein a surface of each of the first contact regions of the first metallic clip that faces away from the first substrate has a sonotrode imprint, wherein the first gap in the first metallic clip extends along a side of the sonotrode imprint, and wherein the first gap in the first metallic clip is longer than the side of the sonotrode imprint.
Example 17. The power semiconductor module of any of examples 13 through 16, wherein a linear dimension of each first gap in the first metallic clip measured in a lateral direction between the corresponding group of first contact regions of the first metallic clip is greater than a linear dimension of the group of first contact regions of the first metallic clip measured in the same lateral direction, and wherein a linear dimension of each second gap in the second metallic clip measured in a lateral direction between the corresponding group of second contact regions of the second metallic clip is greater than a linear dimension of the group of second contact regions of the second metallic clip measured in the same lateral direction.
Example 18. A method of producing a power semiconductor module, the method comprising: attaching a first power semiconductor die to a first substrate; placing a first metallic clip over the first substrate, the first metallic clip having a plurality of first contact regions laterally separated from one another by a first gap in the first metallic clip; and ultrasonically welding the first contact regions of the first metallic clip to either a first metallic region of the first substrate or a first metallic region of the first power semiconductor die.
Example 19. The method of example 18, wherein the first contact regions of the first metallic clip are ultrasonically welded to the first metallic region of the first power semiconductor die and the first metallic clip has a plurality of second contact regions laterally separated from one another by a second gap in the first metallic clip, the method further comprising: attaching a second power semiconductor die to the first substrate; and ultrasonically welding the plurality of second contact regions of the first metallic clip to a first metallic region of the second power semiconductor die.
Example 20. The method of example 18, wherein the first contact regions of the first metallic clip are ultrasonically welded to the first metallic region of the first power semiconductor die and the first metallic clip has a plurality of second contact regions laterally separated from one another by a second gap in the first metallic clip, the method further comprising: attaching a second power semiconductor die the first substrate; ultrasonically welding a plurality of first contact regions of a second metallic clip to the first metallic region of the first substrate; and ultrasonically welding the plurality of second contact regions of the first metallic clip to a first metallic region of the second power semiconductor die.
Example 21. A power semiconductor module, comprising: a first substrate; a first power semiconductor die attached to the first substrate; and a first metallic clip having a plurality of first contact regions ultrasonically welded to either a first metallic region of the first substrate or a first metallic region of the first power semiconductor die, wherein the first contact regions are laterally separated from one another by a first gap in the first metallic clip, wherein the first contact regions of the first metallic clip are connected to a body region of the first metallic clip by a first level transition region of the first metallic clip such that the first contact regions are disposed at a first level and the body region is disposed at a second level different than the first level, wherein the first level is closer to the first substrate than the second level.
Example 22. The power semiconductor module of example 21, further comprising: a second power semiconductor die attached to the first substrate, wherein the first contact regions of the first metallic clip are ultrasonically welded to the first metallic region of the first power semiconductor die, wherein the first metallic clip has a plurality of second contact regions ultrasonically welded to a first metallic region of the second power semiconductor die, wherein the second contact regions of the first metallic clip are laterally separated from one another by a second gap in the first metallic clip, wherein the second contact regions of the first metallic clip are connected to the body region of the first metallic clip by a second level transition region of the first metallic clip such that the second contact regions are disposed at the first level.
Example 23. The power semiconductor module of example 21, further comprising: a second power semiconductor die attached to the first substrate; and a second metallic clip having a plurality of first contact regions ultrasonically welded to the first metallic region of the first substrate, wherein the first contact regions of the first metallic clip are ultrasonically welded to the first metallic region of the first power semiconductor die, wherein the first metallic clip has a plurality of second contact regions ultrasonically welded to a first metallic region of the second power semiconductor die, wherein the second contact regions of the first metallic clip are laterally separated from one another by a second gap in the first metallic clip, wherein the second contact regions of the first metallic clip are connected to the body region of the first metallic clip by a second level transition region of the first metallic clip such that the second contact regions are disposed at the first level.
Example 24. The power semiconductor module of any of examples 21 through 23, wherein a surface of each of the first contact regions of the first metallic clip that faces away from the first substrate has a sonotrode imprint, and wherein each of the first contact regions of the first metallic clip has an area that is less than 4 times an area of the sonotrode imprint.
Example 25. The power semiconductor module of any of examples 21 through 24, wherein a surface of each of the first contact regions of the first metallic clip that faces away from the first substrate has a sonotrode imprint, wherein the first gap in the first metallic clip extends along a side of the sonotrode imprint, and wherein the first gap in the first metallic clip is longer than the side of the sonotrode imprint.
Example 26. The power semiconductor module of any of examples 21 through 25, wherein a linear dimension of the first gap in the first metallic clip measured in a lateral direction between the first contact regions of the first metallic clip is greater than a linear dimension of the first contact regions of the first metallic clip measured in the same lateral direction.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor module, comprising:
a first substrate;
a first power semiconductor die attached to the first substrate; and
a first metallic clip having a plurality of first contact regions ultrasonically welded to either a first metallic region of the first substrate or a first metallic region of the first power semiconductor die,
wherein the first contact regions of the first metallic clip are laterally separated from one another by a first gap in the first metallic clip.

2. The power semiconductor module of claim 1, wherein the first contact regions of the first metallic clip are connected to a body region of the first metallic clip by a level transition region of the first metallic clip such that the first contact regions are disposed at a first level and the body region is disposed at a second level different than the first level, and wherein the first level is closer to the first substrate than the second level.

3. The power semiconductor module of claim 1, further comprising:
a second power semiconductor die attached to the first substrate,
wherein the first contact regions of the first metallic clip are ultrasonically welded to the first metallic region of the first power semiconductor die,
wherein the first metallic clip has a plurality of second contact regions ultrasonically welded to a first metallic region of the second power semiconductor die,
wherein the second contact regions are laterally separated from one another by a second gap in the first metallic clip.

4. The power semiconductor module of claim 3, wherein the first contact regions of the first metallic clip are connected to a body region of the first metallic clip by a first level transition region of the first metallic clip and the second contact regions of the first metallic clip are connected to the body region by a second level transition region of the first metallic clip such that the first contact regions and the second contact regions are disposed at a first level and the body region is disposed at a second level different than the first level, and wherein the first level is closer to the first substrate than the second level.

5. The power semiconductor module of claim 1, further comprising:
a second power semiconductor die attached to the first substrate; and
a second metallic clip having a plurality of first contact regions ultrasonically welded to the first metallic region of the first substrate,
wherein the first contact regions of the first metallic clip are ultrasonically welded to the first metallic region of the first power semiconductor die,
wherein the first metallic clip has a plurality of second contact regions ultrasonically welded to a first metallic region of the second power semiconductor die,
wherein the second contact regions are laterally separated from one another by a second gap in the first metallic clip.

6. The power semiconductor module of claim 5, wherein the first contact regions of the first metallic clip are connected to a body region of the first metallic clip by a first level transition region of the first metallic clip and the second contact regions of the first metallic clip are connected to the body region by a second level transition region of the first metallic clip such that the first contact regions and the second contact regions are disposed at a first level and the body region is disposed at a second level different than the first level, and wherein the first level is closer to the first substrate than the second level.

7. The power semiconductor module of claim 1, wherein the first contact regions of the first metallic clip are ultrasonically welded to the first metallic region of the first power semiconductor die, wherein first metallic region of the first power semiconductor die is a bond pad, and wherein the bond pad has a thickness greater than 5 μm.

8. The power semiconductor module of claim 1, wherein the first contact regions of the first metallic clip are ultrasonically welded to the first metallic region of the first power semiconductor die, and wherein the first metallic region of the first power semiconductor die is a metallic plate attached to a bond pad of the first power semiconductor die.

9. The power semiconductor module of claim 1, wherein a surface of each of the first contact regions of the first metallic clip that faces away from the first substrate has a sonotrode imprint, and wherein each of the first contact regions of the first metallic clip has an area that is less than 4 times an area of the sonotrode imprint.

10. The power semiconductor module of claim 1, wherein a surface of each of the first contact regions of the first metallic clip that faces away from the first substrate has a sonotrode imprint, wherein the first gap in the first metallic clip extends along a side of the sonotrode imprint, and wherein the first gap in the first metallic clip is longer than the side of the sonotrode imprint.

11. The power semiconductor module of claim 1, wherein a linear dimension of the first gap in the first metallic clip measured in a lateral direction between the first contact regions of the first metallic clip is greater than a linear dimension of the first contact regions of the first metallic clip measured in the same lateral direction.

12. The power semiconductor module of claim 1, further comprising:
a second substrate;
a second power semiconductor die attached to the second substrate; and
a second metallic clip having a plurality of first contact regions ultrasonically welded to the first metallic region of the first substrate and a plurality of second contact regions ultrasonically welded to a first metallic region of the second power semiconductor die,
wherein the first contact regions of the first metallic clip are ultrasonically welded to the first metallic region of the first power semiconductor die,
wherein the first contact regions of the second metallic clip are laterally separated from one another by a first gap in the second metallic clip,
wherein the second contact regions of the second metallic clip are laterally separated from one another by a second gap in the second metallic clip.

13. A power semiconductor module, comprising:
a first substrate;
a second substrate;
a plurality of first power semiconductor dies attached to a first metallic region of the first substrate;
a plurality of second power semiconductor dies attached to a first metallic region of the second substrate;
a first metallic clip having a plurality of first contact regions ultrasonically welded to a first metallic region of each of the first power semiconductor dies; and
a second metallic clip having a plurality of first contact regions ultrasonically welded to the first metallic region of the first substrate and a plurality of second contact regions ultrasonically welded to a first metallic region of each of the second power semiconductor dies,
wherein each group of the first contact regions of the first metallic clip ultrasonically welded to the first metallic region of the same first power semiconductor die are laterally separated from one another by a first gap in the first metallic clip,
wherein the first contact regions of the second metallic clip are laterally separated from one another by a first gap in the second metallic clip,
wherein each group of the second contact regions of the second metallic clip ultrasonically welded to the first metallic region of the same second power semiconductor die are laterally separated from one another by a second gap in the second metallic clip.

14. The power semiconductor module of claim 13, wherein:
each group of the first contact regions of the first metallic clip ultrasonically welded to the first metallic region of the same first power semiconductor die are connected to a body region of the first metallic clip by a level transition region of the first metallic clip such that the first contact regions of the first metallic clip are disposed at a first level and the body region of the first metallic clip is disposed at a second level different than the first level;
each group of the second contact regions of the second metallic clip ultrasonically welded to the first metallic region of the same second power semiconductor die are connected to a body region of the second metallic clip by a level transition region of the second metallic clip such that the second contact regions of the second metallic clip are disposed at the first level and the body region of the second metallic clip is disposed at the second level; and
the first level is closer to the first and second substrates than the second level.

15. The power semiconductor module of claim 13, wherein a surface of each of the first contact regions of the first metallic clip that faces away from the first substrate has a sonotrode imprint and an area that is less than 4 times an area of the sonotrode imprint, wherein a surface of each of the second contact regions of the second metallic clip that faces away from the second substrate has a sonotrode imprint and an area that is less than 4 times an area of the sonotrode imprint.

16. The power semiconductor module of claim 13, wherein a surface of each of the first contact regions of the first metallic clip that faces away from the first substrate has a sonotrode imprint, wherein the first gap in the first metallic clip extends along a side of the sonotrode imprint, and wherein the first gap in the first metallic clip is longer than the side of the sonotrode imprint.

17. The power semiconductor module of claim 13, wherein a linear dimension of each first gap in the first metallic clip measured in a lateral direction between the corresponding group of first contact regions of the first metallic clip is greater than a linear dimension of the group of first contact regions of the first metallic clip measured in the same lateral direction, and wherein a linear dimension of each second gap in the second metallic clip measured in a lateral direction between the corresponding group of second contact regions of the second metallic clip is greater than a linear dimension of the group of second contact regions of the second metallic clip measured in the same lateral direction.

18. A method of producing a power semiconductor module, the method comprising:
attaching a first power semiconductor die to a first substrate;
placing a first metallic clip over the first substrate, the first metallic clip having a plurality of first contact regions laterally separated from one another by a first gap in the first metallic clip; and
ultrasonically welding the first contact regions of the first metallic clip to either a first metallic region of the first substrate or a first metallic region of the first power semiconductor die.

19. The method of claim 18, wherein the first contact regions of the first metallic clip are ultrasonically welded to the first metallic region of the first power semiconductor die and the first metallic clip has a plurality of second contact regions laterally separated from one another by a second gap in the first metallic clip, the method further comprising:
attaching a second power semiconductor die to the first substrate; and
ultrasonically welding the plurality of second contact regions of the first metallic clip to a first metallic region of the second power semiconductor die.

20. The method of claim 18, wherein the first contact regions of the first metallic clip are ultrasonically welded to the first metallic region of the first power semiconductor die and the first metallic clip has a plurality of second contact regions laterally separated from one another by a second gap in the first metallic clip, the method further comprising:
attaching a second power semiconductor die the first substrate;
ultrasonically welding a plurality of first contact regions of a second metallic clip to the first metallic region of the first substrate; and
ultrasonically welding the plurality of second contact regions of the first metallic clip to a first metallic region of the second power semiconductor die.
